(19) United States
(12) Patent Application Publication
(10) Pub. No.: US 2019/0212792 A1
(43) Pub. Date: Jul. 11, 2019

(54) Thermally Resistive Electronics Case

(71) Applicant: Lander LLC, Lehi, UT (US)

(72) Inventors: Clark Bailey, Park City, UT (US); Kirk Feller, Draper, UT (US)

(21) Appl. No.: 15/862,916

(22) Filed: Jan. 5, 2018

(51) Int. Cl. G06F 1/20; B23P 15/26; G06F 1/16; B29C 65/00; H04M 1/02; H05K 7/20

(52) U.S. Cl. CPC G06F 1/203; B23P 15/26; G06F 1/1626; B29K 2995/0013; H04M 1/0249; H05K 7/20518; G06F 2200/1633; B29C 66/73521

(57) ABSTRACT

An accessory case includes a shell, a first layer, and a second layer. The shell is shaped to selectively retain an electronic device. The second layer is positioned between the shell and the first layer, and has a higher thermal conductivity than the first layer. The first layer may comprise silicone and/or the second layer may comprise graphite. An accessory case includes an interior volume, a shell, and a plurality of layers. The interior volume is shaped to receive an electronic communications device. The shell has sidewalls shaped to selectively retain the electronic communications device. The plurality of layers are positioned within the shell. The sidewalls and the plurality of layers define the interior volume. The plurality of layers include a thermally conductive material and a thermally resistive material, and the plurality of layers are positioned to limit a rate of heat transfer from the shell to the interior volume.

### FIELD OF THE DISCLOSURE

The embodiments described herein relate generally to a thermally resistive case for electronics. In particular, the disclosure relates to an accessory case for a cellular phone to protect against extreme fluctuations in environmental temperatures.

### BACKGROUND

Users of electronic devices, such as cellular phones and tablet computers, may seek to protect their devices from impacts that frequently occur with such devices. As these devices become more powerful, they may produce increased amounts of heat. Heat exposure to certain components within the device, such as the battery, may decrease performance. In some instances, consumers may utilize an accessory case for their device to assist in dissipating or redirecting the heat produced from within the device. An example of such a case is shown in U.S. patent application Ser. No. 14/836,894.

However, cases for dissipating heat produced from within a device may be inadequate to protect against environmental conditions that can also adversely affect the device's performance. It is not uncommon for the average high and low temperatures in certain geographical regions to fall outside optimal operating ranges, and the use of electronic devices in these temperatures can decrease performance, such as battery life, or cause the device to enter a non-operating state. Other disadvantages of electronic devices and known accessory cases may exist.

### SUMMARY

The present disclosure is directed an accessory case for an electronic device that overcomes some of the problems and disadvantages discussed above.

An embodiment of an accessory case for an electronic device includes a shell, a first layer, and a second layer. The shell is shaped to selectively retain an electronic device. The second layer is positioned between the shell and the first layer, and has a higher thermal conductivity than the first layer. The first layer may comprise silicone and/or the second layer may comprise graphite. The first layer may include a polyester film. The graphite may have a thermal conductivity of 1400-1700 W/(m·K). The first layer may be bonded to the second layer by a pressure sensitive adhesive.

An embodiment of a method of assembling an accessory case for an electronic device comprising positioning a second layer between a shell and a first layer. The shell is shaped to selectively retain an electronic device. The second layer has a higher thermal conductivity than the first layer. The first layer may comprise silicone and/or the second layer may comprise graphite. The first layer may include a polyester film. The graphite may have a thermal conductivity of 1400-1700 W/(m·K). The method may include bonding the first layer to the second layer by a pressure sensitive adhesive.

An embodiment of an accessory case for an electronic communications device includes an interior volume, a shell, and a plurality of layers. The interior volume is shaped to receive an electronic communications device. The shell has sidewalls shaped to selectively retain the electronic communications device. The plurality of layers are positioned within the shell. The sidewalls and the plurality of layers define the interior volume. The plurality of layers include a thermally conductive material and a thermally resistive material, and the plurality of layers are positioned to limit a rate of heat transfer from the shell to the interior volume. The thermally conductive material may be graphite and the thermally resistive material may be silicone. The silicone may be positioned between the interior volume and the graphite.

### BRIEF DESCRIPTION OF THE DRAWINGS

FIG. 1 is an exploded view of an embodiment of an accessory case.

FIG. 2 is a partially exploded view of the embodiment shown in FIG. 1 with an electrical device.

FIG. 3 is a cross-sectional view of the embodiment shown in FIG. 1.

FIG. 4 is an exploded, cross-sectional view of the embodiment shown in FIG. 2.

FIG. 5 is a schematic diagram of an external heat source providing heat to an electronic device within an embodiment of an accessory case.

FIG. 6 is a graphical representation of a measured temperature between the electronic device and the accessory case of FIG. 5.

FIG. 7 is a graphical representation of the temperature of an electronic device in relation to external temperatures.

While the disclosure is susceptible to various modifications and alternative forms, specific embodiments have been shown by way of example in the drawings and will be described in detail herein. However, it should be understood that the disclosure is not intended to be limited to the particular forms disclosed. Rather, the intention is to cover all modifications, equivalents and alternatives falling within the scope of the invention as defined by the appended claims.

### DESCRIPTION

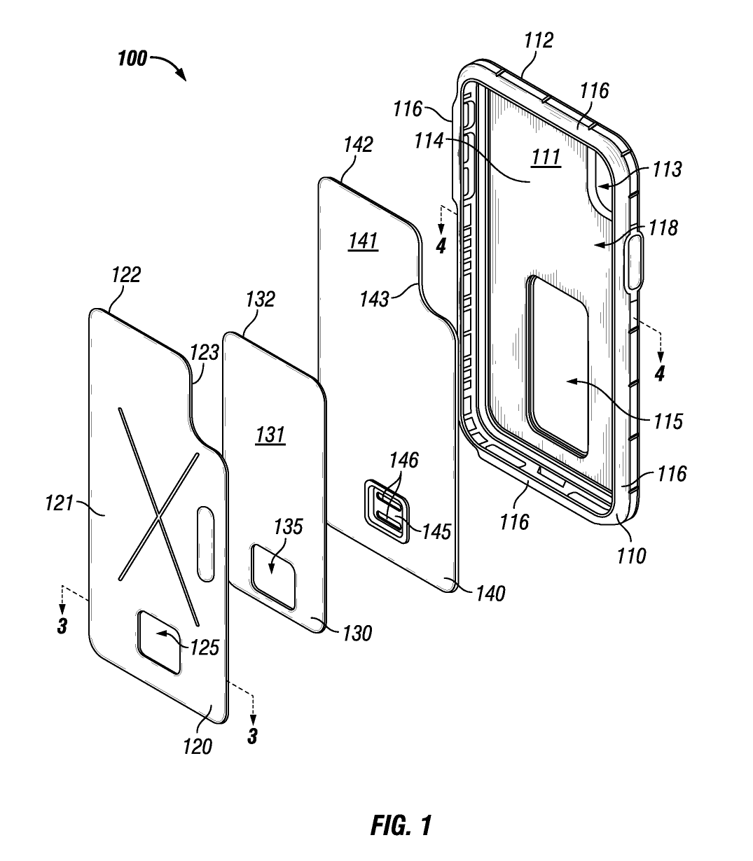

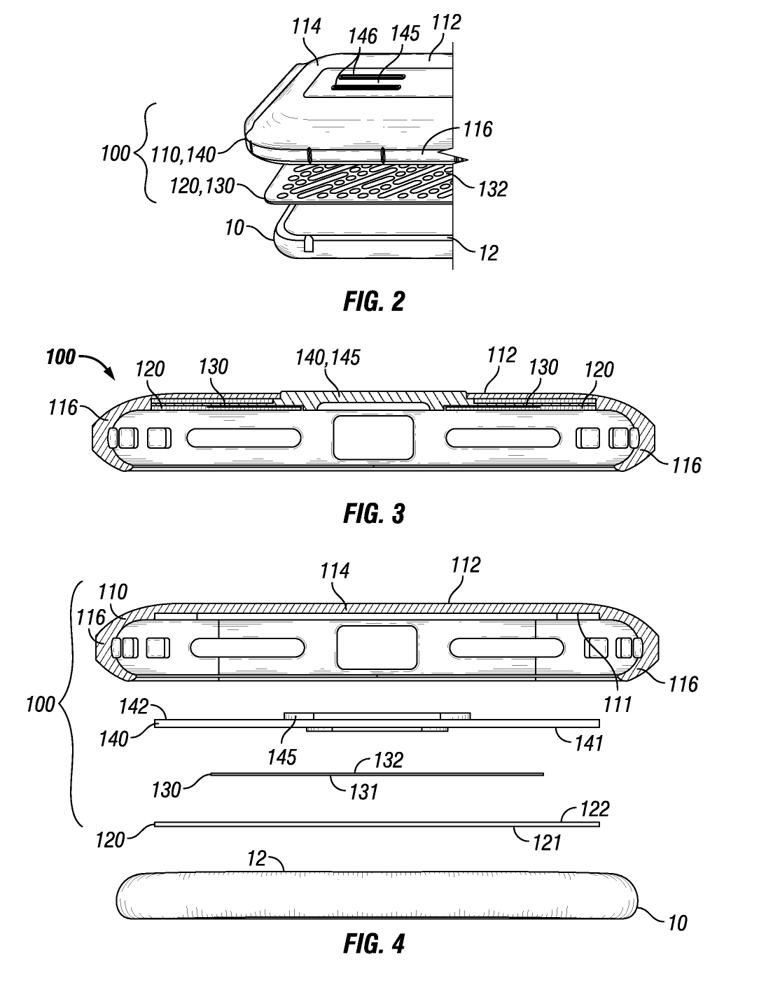

FIG. 1 shows an exploded view of an accessory case 100. Accessory case 100 is configured to receive and selectively retain an electronic device 10 (shown in FIGS. 2 and 4). Accessory case 100 comprises a plurality of layers. Accessory case 100 may include a shell 110, a first layer 120, a second layer 130, and a third layer 140. In some embodiments, third layer 140 may be omitted or be integral to shell 110. Shell 110 includes a bottom wall 114 having a first side 111 and a second side 112 that is opposite first side 111. Shell 110 also includes sidewalls 116 around the perimeter of bottom wall 114. Sidewalls 116 are shaped to receive and selectively retain electronic device 10 (shown in FIGS. 2 and 4). Sidewalls 116 may also include integral bumpers 117 to at least partially absorb external impact forces upon shell 110. Bottom wall 114 may include an optics opening 113 for alignment with a camera and/or flash of electronic device 10. Bottom wall 114 may include a shell aperture 115. When assembled, accessory case 100 include an interior volume 118 defined on one side by first side 121 of first layer 120 and on perimeter sides by sidewalls 116 of shell 110. Interior volume 118 is shaped to receive electronic device 10.

First layer 120 is configured to thermally insulate electronic device 10 (shown in FIGS. 2 and 4) from second layer 130. First layer 120 includes a first side 121 and a second side 122 opposite first side 121. First layer 120 may include an optics profile 123 to allow a camera and/or flash of electronic device 10 to be aligned with optics opening 113 of shell 110. First layer 120 may include a first aperture 125. First side 121 may include ribs that are positioned against a rear side 12 of electronic device 10 (shown in FIGS. 2 and 4) when inserted into accessory case 100. First layer 120 is comprised of a thermally resistive material. As used herein, the term thermally resistive means having a thermal conductivity of less than 1 W/(m·K) at 25° C. In some embodiments, first layer 120 comprises silicone. The silicone may have a thermal conductivity in the range of 0.2-0.4 W/(m·K). In some embodiments, first layer 120 may be comprised of a polyester film upon silicone. The polyester film may provide a bonding surface for a pressure sensitive adhesive. The polyester film may also cause the silicone to be static rather than elastic, which may aid in assembly. An additional layer of pressure sensitive adhesive may be positioned over first layer 120 and second layer 130 for assembly with third layer 140 and/or shell 110.

Second layer 130 is configured to slow the rate of heat transfer to electronic device 10 (shown in FIGS. 2 and 4) from external temperatures. Second layer 130 includes a first side 131 and a second side 132 opposite first side 131. Second layer 130 may include an optics profile (not shown) to allow a camera and/or flash of electronic device 10 to be aligned with optics opening 113 of shell 110. As shown in FIG. 1, a height and width of second layer 130 may be less than a height and/or width of first layer 120 or third layer 140. In some embodiments, the smaller dimensions of second layer 130 may facilitate bonding of a pressure sensitive adhesive on first layer 120 to third layer 140 or shell 110. Second layer 130 may include a second aperture 135. Second layer 130 comprises a thermally conductive material. As used herein, the term thermally conductive means having a thermal conductivity of at least 10 W/(m·K) at 25° C. In some embodiments, second layer 130 comprises graphite. The graphite may include a thermal conductivity in the range of 150-450 W/(m·K). In some embodiments, the graphite may be a synthetic graphite with a thermal conductivity above 450 W/(m·K), such as between 1400 and 1700 W/(m·K). The graphite may have a density in the range of 1.5-2.1 g/cm³. Second layer 130 may be approximately 0.025 mm thick from first side 131 to second side 132. Second layer 130 may include a pressure sensitive adhesive on first side 131 for bonding with second side 122 of first layer 120, or vice versa. In some embodiments, a layer of pressure sensitive adhesive may be laminated over both second side 122 of first layer 120 and second side 132 of second layer 130 with graphite in between. Second layer 130 has a higher thermal conductivity than first layer 120. Second layer 130 may have a higher thermal conductivity than third layer 140.

Third layer 140 may stiffen accessory case 100 and/or provide a more suitable material than shell 110 for adhesion of second layer 130. In some embodiments, third layer 140 comprises polycarbonate. The polycarbonate may have a thermal conductivity in the range of 0.19-0.22 W/(m·K). Third layer 140 includes a first side 141 and a second side 142 opposite first side 141. Third layer 140 may include an optics profile 143 to allow a camera and/or flash of electronic device 10 to be aligned with optics opening 113 of shell 110. Third layer 140 may include a lanyard fastener 145 with two slits 146. Lanyard fastener 145 facilitates connection of a lanyard (not shown) to accessory case 100.

FIG. 2 is a partially exploded view of accessory case 100 retaining electrical device 10. FIG. 3 is a cross-sectional view of accessory case 100 as assembled. As designated in FIG. 1, the cross-sectional view of FIG. 3 is through a lower portion of accessory case 100 and through lanyard fastener 145. For further illustration, FIG. 4 shows an exploded, cross-sectional view of accessory case 100 and electronic device 10 through an upper portion of accessory case 100. As shown in FIGS. 2 and 3, lanyard fastener 145 is received into shell aperture 115 of shell 110 (best shown in FIG. 1) and slits 146 of lanyard fastener 145 are accessible from second side 112 of shell 110. The other side of slits 146 of lanyard fastener 145 may be accessed through first aperture 125 and second aperture 135. Electronic device 10 is selectively retained by sidewalls 116 and rear side 12 of electronic device 10 is positioned adjacent to first layer 120 and second layer 130. Electronic device 10 may be an electronic communications device, such as a cellular phone or tablet computer.

As best seen in FIG. 4, first side 121 of first layer 120 is oriented away from bottom wall 114 of shell 110 to receive rear side 12 of electronic device 10. First side 131 of second layer 130 is adjacent to second side 122 of first layer 120. Second side 132 of second layer 130 is adjacent to first side 141 of third layer 140. First side 111 of shell 110 is adjacent to second side 142 of third layer 140.

Accessory case 100 passively regulates the temperature of electronic device 10. High or low environmental temperatures may be received to shell 110 of accessory case 100 and are passively transferred into the thermally conductive second layer 130. The heat is dissipated within second layer 130. First layer 120 prevents or limits thermal transfer to electronic device 10 from second layer 130. As the rate of heat transfer to electronic device 10 is slowed, electronic device 10 may stay within optimal operating temperatures for a longer period of time. For instance, low environmental temperatures against shell 110 of accessory case 100 may be dissipated into second layer 130 and the rate of temperature decrease of electronic device 10 may be slowed. Similarly, high environmental temperatures against shell 110 of accessory case 100 may be dissipated into second layer 130 and the rate of temperature increase of electronic device 10 may be slowed.

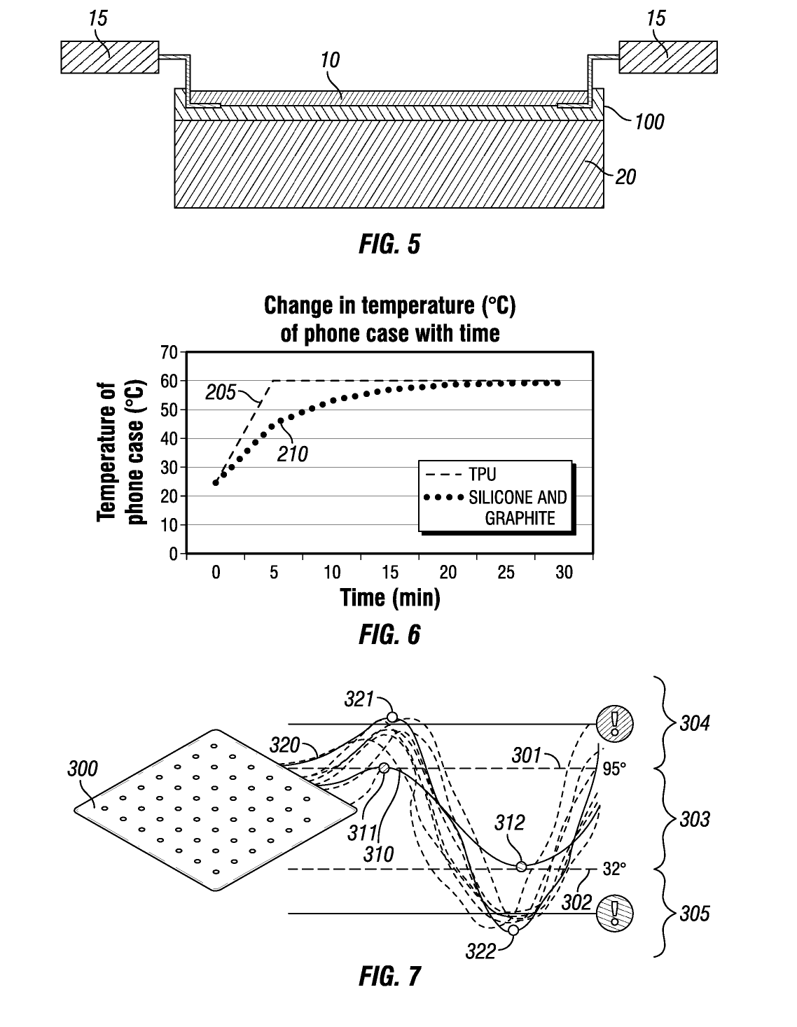

FIG. 5 is a schematic diagram of an external heat source 20 providing heat to an electronic device 10 within an accessory case 100. A pair of thermocouples 15 were positioned between electronic device 10 and accessory case 100 to measure the change in temperature of electronic device 10. Table 1, below, shows the results of a test that was conducted. As shown, thermocouples 15 positioned at electronic device 10 initially read 25.6° C. A thermally conductive second layer 130 of graphite and a thermally resistive first layer 120 of silicone positioned adjacent to electronic device 10 limited the rate of heat transfer from a 40° C. external heat source 20 such that it took twenty minutes for the temperature of the thermocouples to exceed the temperature of external heat source 20.

TABLE 1

| Time | Heat Plate | Thermocouple |
|---|---|---|
| (min) | Temperature (° C.) | (° C.) |
| 0 | 40 | 25.60 |
| 5 | 40 | 32.06 |
| 10 | 40 | 37.01 |
| 15 | 40 | 39.07 |
| 20 | 40 | 40.03 |
| 25 | 40 | 40.59 |
| 30 | 40 | 41.00 |

Additional tests compared the rate of heat transfer of an accessory case 100 with a thermally conductive second layer 130 of natural graphite and a thermally resistive first layer 120 of silicone positioned adjacent to electronic device 10 to an accessory case made of thermoplastic polyurethane (TPU). Table 2, below, shows the results of a test that was conducted using a 60° C. external heat source applied over thirty minutes. As shown, the use of natural graphite and silicone slowed the rate of heat transfer to electronic device 10. It is anticipated that the use of an artificial graphite, having a greater thermal conductivity, would be more efficient at limiting heat transfer to electronic device 10 than natural graphite. FIG. 6 is a graphical representation 200 of the test results shown in Table 2. In particular, data 205 shows the time-correlated temperature of a known TPU accessory case and data 210 shows the time-correlated temperature of the accessory case with natural graphite and silicone.

TABLE 2

| Time | Heat Plate | | Silicone & |
|---|---|---|---|
| (min) | Temperature (° C.) | TPU (° C.) | Graphite (° C.) |
| 0 | 60 | 24.9 | 24.7 |
| 5 | 60 | 60.4 | 45.1 |
| 10 | 60 | 60.5 | 53.2 |
| 15 | 60 | 60.4 | 57 |
| 20 | 60 | 60.3 | 58.6 |
| 25 | 60 | 60.3 | 59.1 |
| 30 | 60 | 60.4 | 59.3 |

FIG. 7 is a graphical representation of a temperature curve 310 of an electronic device 300 in relation to environmental temperatures 320. Each electronic device 300 may have an upper operating limit 301 and a lower operating limit 302, with an operating temperature range 303 therebetween. For example, some electronic devices 300 may have an operating temperature range of between 32° F. and 95° F. (0-35° C.). Operating temperature range 303 may be dictated by components of electronic device 300, such as battery type, which are adversely impacted by extreme temperatures. Non-operating conditions may include high temperature conditions 304 that exceed upper operating limit 301 and low temperature conditions 305 that are below lower operating limit 302.

Environmental temperatures 320 show extreme temperature fluctuations from a high environmental temperature 321 that exceeds upper operating limit 301 of electronic device 300 to a low environmental temperature 322 that is below lower operating limit 302 of electronic device 300. With an accessory case as disclosed herein, temperature curve 310 of electronic device 300 may fluctuate between a maximum device temperature 311 that does not exceed upper operating limit 301 and a minimum device temperature 312 that is above lower operating limit 302. It is recognized that maximum device temperature 311 and minimum device temperature 312 may depart outside operating temperature range 303 depending on the duration and intensity of environmental temperatures 320. Nevertheless, as illustrated in FIG. 7, the rate of heat transfer is slowed and the time until temperature curve 310 of electronic device 300 departs from operating temperature range 303 is delayed.

A method includes assembling accessory case 100. The method include positioned second layer 130 between shell 110 and first layer 120. The method may include applying a pressure sensitive adhesive to bond first layer 120 and second layer 130. The method may include positioning third layer 140 between second layer 130 and shell 110. The method may include applying an additional layer of pressure sensitive adhesive over first layer 120 and second layer 130 for assembly with third layer 140 and/or shell 110. The method may include selectively retaining electronic device 10 within assembled accessory case 100.

Although this disclosure has been described in terms of certain preferred embodiments, other embodiments that are apparent to those of ordinary skill in the art, including embodiments that do not provide all of the features and advantages set forth herein, are also within the scope of this disclosure. Accordingly, the scope of the present disclosure is defined only by reference to the appended claims and equivalents thereof.

1. An accessory case for an electronic device, the accessory case comprising:
a shell shaped to selectively retain an electronic device;
an interior volume defined by the shell and shaped to receive the electronic device;
a first layer comprising silicone; and
a second layer positioned between the shell and the first layer, the first layer positioned between the interior volume and the second layer, the second layer having a higher thermal conductivity than the first layer.

2. (canceled)

3. The accessory case of claim 1, wherein the first layer further comprises a polyester film.

4. The accessory case of claim 1, wherein the second layer comprises graphite.

5. The accessory case of claim 4, wherein the graphite has a thermal conductivity of 1400-1700 W/(m·K).

6. The accessory case of claim 4, further comprising a third layer positioned between the shell and the second layer.

7. The accessory case of claim 6, wherein the third layer comprises polycarbonate.

8. The accessory case of claim 4, wherein the electronic device that the shell is shaped to selectively retain is a cellular phone.

9. The accessory case of claim 4, wherein the first layer is bonded to the second layer by a pressure sensitive adhesive.

10. A method of assembling an accessory case for an electronic device, the method comprising positioning a second layer between a shell and a first layer, the shell being shaped to selectively retain an electronic device and the second layer having a higher thermal conductivity than the first layer, wherein the first layer comprises silicone.

11. (canceled)

12. The method of claim 10, wherein the first layer further comprises a polyester film.

13. The method of claim 10, wherein the second layer comprises graphite.

14. The method of claim 13, wherein the graphite has a thermal conductivity of 1400-1700 W/(m·K).

15. The method of claim 14, further comprising positioning a third layer between the shell and the second layer.

16. The method of claim 15, wherein the third layer comprises polycarbonate.

17. The method of claim 13, wherein the electronic device that the shell is shaped to selectively retain is a cellular phone.

18. The method of claim 13, further comprising bonding the first layer to the second layer by a pressure sensitive adhesive.

19. An accessory case for an electronic communications device, the accessory case comprising:
an interior volume shaped to receive an electronic communications device;
a shell having sidewalls shaped to selectively retain the electronic communications device; and
a plurality of layers positioned within the shell, the sidewalls and the plurality of layers defining the interior volume, the plurality of layers including a thermally conductive material and a thermally resistive material, the plurality of layers positioned to limit a rate of heat transfer from the shell to the interior volume, wherein the thermally conductive material is graphite and the thermally resistive material is silicone, the silicone being positioned between the interior volume and the graphite.

20. (canceled)
